(19) United States
(12) Patent Application Publication
(10) Pub. No.: US 2005/0217717 A1
(43) Pub. Date: Oct. 6, 2005

(54) Photovoltaic cell and method of manufacture of photovoltaic cells

(76) Inventor: Sadeg Faris, Pleasantville, NY (US)

Correspondence Address: Reveo Inc, 85 Executive Boulevard, Elmsford, NY, 10523, US

(21) Appl. No.: 10/501,790

(22) PCT Filed: Jan. 2, 2003
(86) PCT No.: PCT/US03/00064

§ 371 Date: Mar. 24, 2005

Related U.S. Application Data
(60) Provisional application No. 60/346,128, filed on Jan. 2, 2002.

(51) Int. Cl. H01L 31/00

(52) U.S. Cl. 136/252

(57) ABSTRACT

A photovoltaic cell is produced from a multiple layer substrate. The multiple layer substrate generally includes a first layer suitable for having photovoltaic cells formed therein or thereon, wherein the selectively attached or bonded to a second layer. A method to form a photovoltaic cell or a plurality of photovoltaic cells generally comprises selectively adhering a first layer to a second substrate.

### BACKGROUND OF THE INVENTION

PV Cells

As worldwide energy demands increase in the future, the need for cost efficient and reliable alternative energy resources increases. The energy emitted from the sun may provide such an alternative energy resource. Solar cells, or photovoltaic cells (PV cells), are considered a major candidate for obtaining energy from the sun, since they can convert sunlight directly to electricity, can provide long term power at low operation cost, and is free of pollution associated with energy generation. Presently, PV cells furnish long-term power for satellites and space vehicles. PV cells have also been successfully employed in small-scale terrestrial applications.

Primary barriers to more widespread use of solar cells as a larger scale power source include the cost of the cells (manufacturing costs and/or material costs), operating efficiencies of solar cells, or both cost and efficiencies.

Operation of Typical PV Cells

Single Junction Cells

In a typical single-junction photovoltaic cell, a material such as silicon is doped with atoms from an element with one more or less electrons than occurs in the substrate (e.g., silicon), resulting in a p-n junction between the layers. When photons strike the cell, those with energy larger or equal to the semiconductor bandgap E_{g} (which varies depending on the materials used, depth of the p-n junction, etc.) will be able to excite electrons from N-type silicon to P-type silicon to create a current as it moves across the p-n junction under the effect of an electric field. The current may be gathered in various currents and voltages through series and/or parallel arrays.

The efficiency of single-junction solar cells is generally based on the limited E_{g}. When the cell is exposed to the solar spectrum, a photon with energy less than E_{g} makes essentially no contribution to the cell output, a photon with energy greater than E_{g} contributes an energy E_{g} to the cell output, and the excess over E_{g} is essentially wasted as heat.

Silicon, Derivatives and Other Materials for PV Cells

Common materials for solar cells include highly purified silicon, which is sliced into wafers from single-crystal ingots or grown as thin crystalline sheets or ribbons. The cost, however, is not practical because of the cost of ingot growing, slicing, doping and polishing, and the unnecessary bulk of the silicon material itself. Much material is wasted, and accordingly energy efficiency decreased, since solar cells need to be only several optical wavelengths in thickness.

Another method of forming thin layer solar cells involves drawing thin sheets from molten silicon.

Still another method of forming thin layer solar cells involves depositing gaseous silicon materials into films.

Polycrystalline cells are also used, which are inherently less efficient than single crystal cells, but are also less expensive to produce.

Silicon cells typically have maximum AM1.5, 1 sun efficiencies of about 22.3%. Other materials are also used to increase efficiencies, such as gallium arsenide, with maximum AM1.5, 1 sun efficiencies of about 22.3%, but these materials are also expensive.

Multi-Junction Cells

Another approach to increasing efficiencies is to rely on multispectral conversion, wherein several cells are stacked on order of decreasing bandgaps. The top cell absorbs the UV radiation and photons corresponding to the E_{g} of that cell. The lower cells (typically one or two) absorb photons with successively lower energy corresponding to the cells' bandgaps. In this manner, varying cells (i.e., having different E_{g} values) may be stacked to maximize efficiency, greater than about 30%. For two bandgaps in series, the ideal maximum efficiency is 50%, with E_{g1}=1.56 eV and E_{g2}=0.94 eV. For three bandgaps, the ideal maximum efficiency is 56%, with E_{g1}=1.75 eV, E_{g2}=1.18 eV, and E_{g3}=0.75 eV. Systems using more than three bandgaps demonstrate very slow efficiency increases—for example, at 36 bandgaps, the maximum efficiency is 72%.

The tandem cell described above configuration is inherently more expensive than single-junction cells. The tandem configurations are typically grown, either atop other cell layers, or separately and transferred. For example, epitaxial lift-off has been used to produce thin films, wherein a photovoltaic material may be grown in conjunction with a release layer to facilitate lift-off. However, conventional methods of growing or stacking two or three cells atop one another results in cells that are very expensive, especially on a cost per watt basis. Further, to transfer energy from the cells in the tandem configuration, interconnects must be formed, typically on the edge of the stack of cells, which is a key limitation to cost effective tandem solar cells.

Accordingly, a need remains in the art for solar cells that combine solar conversion efficiency with affordable manufacturing to allow mass production, and consequently reduce the cost per unit power.

### SUMMARY OF THE INVENTION

The above-discussed and other problems and deficiencies of the prior art are overcome or alleviated, and the objects of the invention are attained, by the several methods and apparatus of the present invention. A photovoltaic cell is produced from a multiple layer substrate. The multiple layer substrate generally includes a first layer suitable for having photovoltaic cells formed therein or thereon, wherein the selectively attached or bonded to a second layer. A method to form a photovoltaic cell or a plurality of photovoltaic cells generally comprises selectively adhering a first layer to a second substrate.

In one embodiment, a multiple layer substrate includes a first layer suitable for having photovoltaic cells formed therein or thereon selectively attached or bonded to a second substrate layer.

The selective bonding generally includes one or more regions of strong bonding and one or more regions of weak bonding. Solar or photovoltaic cells, or portions thereof, may be formed in or upon the one or more regions of weak bonding. Since the second layer is utilized to provide support and thermal stability, the first layer may be very thin (e.g., less than ten, five, two, or even one micron). Thus, manufacturing of thin layer solar cells, which oftentimes must be accomplished under harsh operating conditions, is possible, while maintaining the mechanical and thermal integrity of the first substrate layer. Subsequently, the first layer with the solar cells or solar cells components may be readily removed from the second layer by, for example, peeling or other convenient methods. Since the solar cells or components thereof are formed within or upon weak bond regions of the first layer, they are minimally affected, and preferably not affected at all, during removal, such that little or no subsequent structure repair or processing is required.

The above-discussed and other features and advantages of the present invention will be appreciated and understood by those skilled in the art from the following detailed description and drawings.

### BRIEF DESCRIPTION OF THE DRAWINGS

FIG. 1A schematically depicts a multiple layered substrate for use in processing photovoltaic cells as described herein;

FIG. 1B schematically depicts another embodiment of a multiple layered substrate for use in processing photovoltaic cells as described herein;

FIGS. 2-13 depict various treatment techniques for selective adhesion of the layers of the structure in FIGS. 1A and 1B;

FIGS. 14-20 depict various bonding geometries for the structure of FIGS. 1A and 1B;

FIGS. 21-32 depict various debonding techniques;

FIG. 33 shows one embodiment of a photovoltaic cell set;

FIGS. 34A-34C show tandem photovoltaic cells;

FIG. 35 shows another embodiment of a photovoltaic cell set, using tandem photovoltaic cells; and

FIG. 36 depicts an embodiment of a tandem array of photovoltaic cell sets.

### DETAILED DESCRIPTION OF THE ILLUSTRATIVE EMBODIMENTS

The present invention is related to efficiently manufacturing various types of solar cells. Prior to discussion of specific formation of these solar cells, a discussion of the starting substrates is presented, as set forth in Applicant's copending U.S. patent application Ser. No. 09/950,909 filed on Sep. 12, 2001 entitled “Thin films and Production Methods Thereof”, incorporated by reference herein. This substrate, referred to as a selectively bonded multiple layer substrate, allows for processing of one or more solar cells on a wafer as is known, but allows the cell layer of the wafer to be readily removed, preferably without mechanical grinding or other etch-back techniques, thereby realizing substantial cost savings and reliability advantages over known solar cell manufacturing techniques.

Virtually any types of solar cell may benefit from the teachings herein. Hereinafter, the term “solar device” shall refer to all types of solar cells.

Formation of Selectively Bonded Device Layer

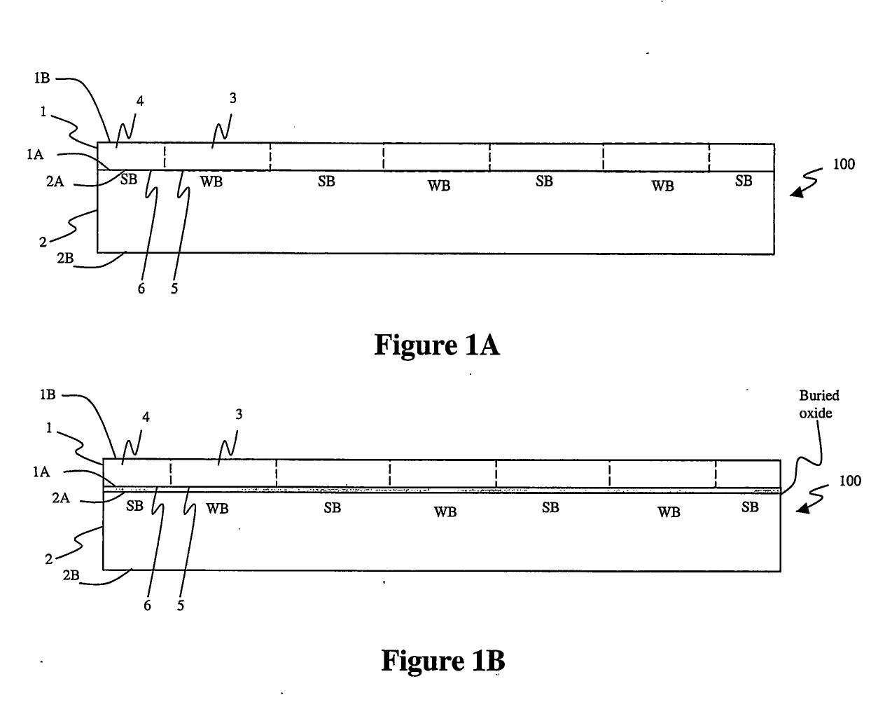

Referring to FIG. 1A, a selectively bonded multiple layer substrate 100 is shown. The multiple layer substrate 100 includes a layer 1 having an exposed surface 1B, and a surface 1A selectively bonded to a surface 2A of a layer 2. Layer 2 further includes an opposing surface 2B. Layer 1 generally serves as a layer intended to process one or more devices therein or thereon, including but not limited to photovoltaic devices as described herein. Layer 2 generally serves as a supporting substrate during processing of the one or more devices in or upon layer 1.

Alternatively, and referring now to FIG. 1B, a buried oxide layer may be formed at a certain depth within the multiple layered substrate. For example, a buried oxide layer may be formed generally at the interface of the device layer 1 and layer 2, to form an SOI structure including a base substrate, a buried oxide layer and a semiconductor layer.

The oxide layer may be formed prior to selective bonding of the device layer to the bulk substrate. In one embodiment, an oxide layer may be formed at a desired depth, as is known to those skilled in the art. Thereafter, the layer above the oxide layer may be removed, for example, by cleavage propagation, ion implantation followed by mechanical separation (e.g., cleavage propagation, normal to the plane of structure 100, parallel to the plane of structure 100, in a peeling direction, or a combination thereof), or ion implantation followed by heat, light, and/or pressure induced layer splitting. Then, the removed layer (or a separately derived layer) may be selectively bonded to the top surface of the substrate layer 2 having the oxide layer thereon.

The oxide layer may alternatively be formed after to selective bonding of the device layer to the bulk substrate. For example, in one embodiment, the oxide layer may be formed by oxygen implanting to a desired buried oxide layer depth after selective bonding of the device layer to the bulk substrate.

Layers 1 and 2 may be derived from various sources, including wafers or fluid material deposited to form films and/or substrate structures. Where the starting material is in the form of a wafer, any conventional process may be used to derive layers 1 and/or 2. For example, layer 2 may consist of a wafer, and layer 1 may comprise a portion of the same or different wafer. The portion of the wafer constituting layer 1 may be derived from mechanical thinning (e.g., mechanical grinding, cutting, polishing; chemical-mechanical polishing; polish-stop; or combinations including at least one of the foregoing), cleavage propagation, ion implantation followed by mechanical separation (e.g., cleavage propagation, normal to the plane of structure 100, parallel to the plane of structure 100, in a peeling direction, or a combination thereof), ion implantation followed by heat, light, and/or pressure induced layer splitting, chemical etching, or the like. Further, either or both layers 1 and 2 may be deposited or grown, for example by chemical vapor deposition, epitaxial growth methods, or the like.

In general, to form the selectively bonded multiple layer substrate 100, layer 1, layer 2, or both layers 1 and 2 are treated to define regions of weak bonding 5 and strong bonding 6. The layers are then bonded together, wherein the regions of weak bonding 5 are in a condition to allow processing of a useful device or structure. Accordingly, removal of layer 1 having the useful devices such as photovoltaic cells is facilitated, and the potential of damage to the useful devices is minimized or eliminated.

In general, layers 1 and 2 are compatible. That is, the layers 1 and 2 constitute compatible thermal, mechanical, and/or crystalline properties. In certain preferred embodiments, layers 1 and 2 are the same materials. Of course, different materials may be employed, but preferably selected for compatibility.

One or more regions of layer 1 are defined to serve as the substrate region within or upon which one or more structures, such as photovoltaic devices may be formed. These regions may be of any desired pattern, as described further herein. The selected regions of layer 1 may then be treated to minimize bonding, forming the weak bond regions 5. Alternatively, corresponding regions of layer 2 may be treated (in conjunction with treatment of layer 1, or instead of treatment to layer 1) to minimize bonding. Further alternatives include treating layer 1 and/or layer 2 in regions other than those selected to form the structures, so as to enhance the bond strength at the strong bond regions 6.

After treatment of layer 1 and/or layer 2, the layers are aligned and bonded. The bonding may be by any suitable method, as described further herein. Additionally, the alignment may be mechanical, optical, or a combination thereof. It should be understood that the alignment at this stage may not, be critical, insomuch as there are generally no structures formed on layer 1. However, if both layers 1 and 2 are treated, alignment may be required to minimized variation from the selected substrate regions.

The multiple layer substrate 100 is formed such that the user may process any structure or device using conventional fabrication techniques, or other techniques that become known as the various related technologies develop. Certain fabrication techniques subject the substrate to extreme conditions, such as high temperatures, pressures, harsh chemicals, or a combination thereof. Thus, the multiple layer substrate 100 is preferably formed so as to withstand these conditions.

Useful structures or devices may be formed in or upon regions 3, which partially or substantially overlap weak bond regions 5. Accordingly, regions 4, which partially or substantially overlap strong bond regions 6, generally do not have structures therein or thereon. After formation of useful devices such as photovoltaic devices within or upon layer 1 of the multiple layer substrate 100, layer 1 may subsequently be debonded. The debonding may be by any known technique, such as peeling or otherwise detaching layer 1 from layer 2, without the need to directly subject the useful devices to detrimental delamination techniques. Since useful devices are not generally formed in or on regions 4, these regions may be subjected to debonding processing, such as ion implantation and/or etching, without detriment to the structures formed in or on regions 3.

Formation of Bond Regions

To form weak bond regions 5, surfaces 1A, 2A, or both may be treated at the locale of weak bond regions 5 to form substantially no bonding or weak bonding. Alternatively, the weak bond regions 5 may be left untreated, whereby the strong bond region 6 is treated to induce strong bonding. Region 4 partially or substantially overlaps strong bond region 6. To form strong bond region 4, surfaces 1A, 2A, or both may be treated at the locale of strong bond region 6. Alternatively, the strong bond region 6 may be left untreated, whereby the weak bond region 5 is treated to induce weak bonding. Further, both regions 5 and 6 may be treated by different treatment techniques, wherein the treatments may differ qualitatively or quantitatively.

After treatment of one or both of the groups of weak bond regions 5 and strong bond regions 6, layers 1 and 2 are bonded together to form a substantially integral multiple layer substrate 100. Thus, as formed, multiple layer substrate 100 may be subjected to harsh environments during processing of photovoltaic devices or other useful devices therein or thereon, particularly in or on regions 3 of layer 1.

The phrase “weak bonding” or “weak bond” generally refers to a bond between layers or portions of layers that may be readily overcome, for example by debonding techniques such as peeling, other mechanical separation, heat, light, pressure, vacuum, or combinations comprising at least one of the foregoing debonding techniques. These debonding techniques minimally defect or detriment the layers 1 and 2, particularly in the vicinity of weak bond regions 5.

The treatment of one or both of the groups of weak bond regions 5 and strong bond regions 6 may be effectuated by a variety of methods. The important aspect of the treatment is that weak bond regions 5 are more readily debonded (in a subsequent debonding step as described further herein) than the strong bond regions 6. This minimizes or prevents damage to the regions 3, which include solar or photovoltaic cells therein or thereon, during debonding. Further, the inclusion of strong bond regions 6 enhances mechanical integrity of the multiple layer substrate 100 especially during processing of the cells. Accordingly, subsequent processing of the layer 1, when removed with solar or photovoltaic cells therein or thereon, is minimized or eliminated.

The treatment of one or both of the groups of weak bond regions 5 and strong bond regions 6 may be effectuated by a variety of methods. The important aspect of the treatment is that weak bond regions 5 are more readily debonded (in a subsequent debonding step as described further herein) than the strong bond regions 6. This minimizes or prevents damage to the regions 3, which may include useful structures thereon, during debonding. Further, the inclusion of strong bond regions 6 enhances mechanical integrity of the multiple layer substrate 100 especially during structure processing. Accordingly, subsequent processing of the layer 1, when removed with useful structures therein or thereon, is minimized or eliminated.

The ratio of the bond strengths of the strong bond regions to the weak bond regions (SB/WB) in general is greater than 1. Depending on the particular configuration of the strong bond regions and the weak bond regions, and the relative areas of the strong bond regions and the weak bond regions, the value of SB/WB may approach infinity. That is, if the strong bond areas are sufficient in size and strength to maintain mechanical and thermal stability during processing, the bond strength of the weak bond areas may approach zero. However, the ratio SB/WB may vary considerably, since strong bonds strengths (in typical silicon and silicon derivative, e.g., SiO₂, wafers) may vary from about 500 millijoules per squared meter (mj/m²) to over 5000 mj/m² as is taught in the art (see, e.g., Q. Y. Tong, U. Goesle, Semiconductor Wafer Bonding, Science and Technology, pp. 104-118, John Wiley and Sons, New York, N.Y. 1999, which is incorporated herein by reference). However, the weak bond strengths may vary even more considerably, depending on the materials, the type of photovoltaic cell to be processed in or on the weak bond region, the bonding and debonding techniques selected, the area of strong bonding compared to the area of weak bonding, the strong bond and weak bond configuration or pattern on the wafer, and the like. For example, where ion implantation is used as a step to debond the layers, a useful weak bond area bond strength may be comparable to the bond strength of the strong bond areas after ion implantation and/or related evolution of microbubbles at the implanted regions. Accordingly, the ratio of bond strengths SB/WB is generally greater than 1, and preferably greater than 2, 5, 10, or higher, depending on the selected debonding techniques and possibly the choice of the useful structures or devices to be formed in the weak bond regions.

The particular type of treatment of one or both of the groups of weak bond regions 5 and strong bond regions 6 undertaken generally depends on the materials selected. Further, the selection of the bonding technique of layers 1 and 2 may depend, at least in part, on the selected treatment methodology. Additionally, subsequent debonding may depend on factors such as the treatment technique, the bonding method, the materials, the type or existence of useful structures, or a combination comprising at least one of the foregoing factors. In certain embodiments, the selected combination of treatment, bonding, and subsequent debonding (i.e., which may be undertaken by an end user that forms useful structures in regions 3 or alternatively, as an intermediate component in a higher level device) obviates the need for cleavage propagation to debond layer 1 from layer 2 or mechanical thinning to remove layer 2, and preferably obviates both cleavage propagation and mechanical thinning. Accordingly, the underlying substrate may be reused with minimal or no processing, since cleavage propagation or mechanical thinning damages layer 2 according to conventional teachings, rendering it essentially useless without further substantial processing.

One treatment technique may rely on variation in surface roughness between the weak bond regions 5 and strong bond regions 6. The surface roughness may be modified at surface 1A (FIG. 4), surface 2A (FIG. 5), or both surfaces 1A and 2A. In general, the weak bond regions 5 have higher surface roughness 7 (FIGS. 4 and 5) than the strong bond regions 6. In semiconductor materials, for example the weak bond regions 5 may have a surface roughness greater than about 0.5 nanometer (nm), and the strong bond regions 4 may have a lower surface roughness, generally less than about 0.5 nm. In another example, the weak bond regions 5 may have a surface roughness greater than about 1 nm, and the strong bond regions 4 may have a lower surface roughness, generally less than about 1 nm. In a further example, the weak bond regions 5 may have a surface roughness greater than about 5 nm, and the strong bond regions 4 may have a lower surface roughness, generally less than about 5 nm. Surface roughness can be modified by etching (e.g., in KOH or HF solutions) or deposition processes (e.g., low pressure chemical vapor deposition (LPCVD) or plasma enhanced chemical vapor deposition (PECVD)). The bonding strength associated with surface roughness is more fully described in, for example, Gui et al., “Selective Wafer Bonding by Surface Roughness Control”, Journal of The Electrochemical Society, 148 (4) G225-G228 (2001), which is incorporated by reference herein.

In a similar manner (wherein similarly situated regions are referenced with similar reference numbers as in FIGS. 4 and 5), a porous region 7 may be formed at the weak bond regions 5, and the strong bond regions 6 may remain untreated. Thus, layer 1 minimally bonds to layer 2 at locale of the weak bond regions 5 due to the porous nature thereof. The porosity may be modified at surface 1A (FIG. 4), surface 2A (FIG. 5), or both surfaces 1A and 2A. In general, the weak bond regions 5 have higher porosities at the porous regions 7 (FIGS. 4 and 5) than the strong bond regions 6.

Another treatment technique may rely on selective etching of the weak bond regions 5 (at surfaces 1A (FIG. 4), 2A (FIG. 5), or both 1A and 2A), followed by deposition of a photoresist or other carbon containing material (e.g., including a polymeric based decomposable material) in the etched regions. Again, similarly situated regions are referenced with similar reference numbers as in FIGS. 4 and 5. Upon bonding of layers 1 and 2, which is preferably at a temperature sufficient to decompose the carrier material, the weak bond regions 5 include a porous carbon material therein, thus the bond between layers 1 and 2 at the weak bond regions 5 is very weak as compared to the bond between layers 1 and 2 at the strong bond region 6. One skilled in the art will recognize that depending on the circumstances, a decomposing material will be selected that will not out-gas, foul, or otherwise contaminate the substrate layers 1 or 2, or any useful structure to be formed in or upon regions 3.

A further treatment technique may employ irradiation to attain strong bond regions 6 and/or weak bond regions 5. In this technique, layers 1 and/or 2 are irradiated with neutrons, ions, particle beams, or a combination thereof to achieve strong and/or weak bonding, as needed. For example, particles such as He⁺, H⁺, or other suitable ions or particles, electromagnetic energy, or laser beams may be irradiated at the strong bond regions 6 (at surfaces 1A, 2A, or both 1A and 2A). It should be understood that this method of irradiation differs from ion implantation for the purpose of delaminating a layer, generally in that the doses and/or implantation energies are much less (e.g., on the order of 1/100^{th} to 1/1000^{th} of the dosage used for delaminating).

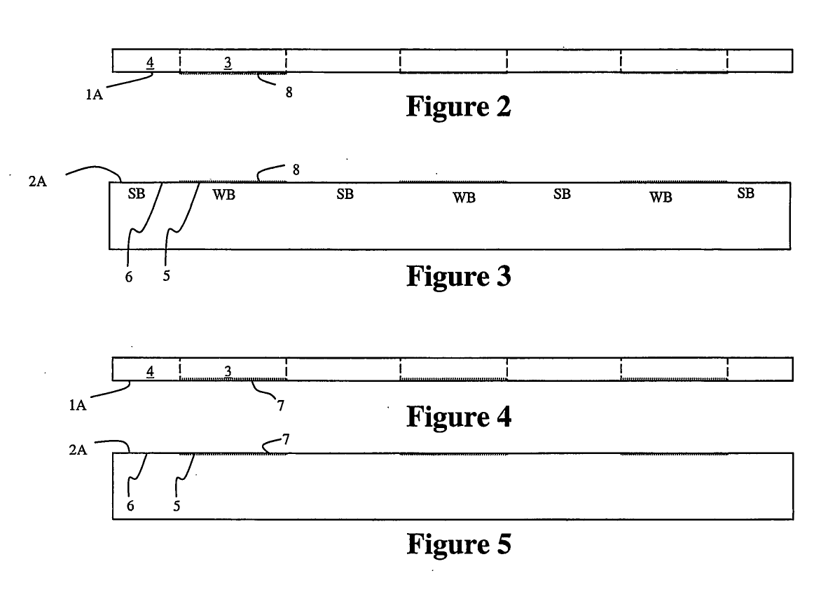

An additional treatment technique includes use of a slurry containing a solid component and a decomposable component on surface 1A, 2A, or both 1A and 2A. The solid component may be, for example, alumina, silicon oxide (SiO₍ₓ₎), other solid metal or metal oxides, or other material that minimizes bonding of the layers 1 and 2. The decomposable component may be, for example, polyvinyl alcohol (PVA), or another suitable decomposable polymer. Generally, a slurry 8 is applied in weak bond region 5 at the surface 1A (FIG. 2), 2A (FIG. 3), or both 1A and 2A. Subsequently, layers 1 and/or 2 may be heated, preferably in an inert environment, to decompose the polymer. Accordingly, porous structures (comprised of the solid component of the slurry) remain at the weak bond regions 5, and upon bonding, layers 1 and 2 do not bond at the weak bond regions 5.

A still further treatment technique involves etching the surface of the weak bond regions 5. During this etching step, pillars 9 are defined in the weak bond regions 5 on surfaces 1A (FIG. 8), 2A (FIG. 9), or both 1A and 2A. The pillars may be defined by selective etching, leaving the pillars behind. The shape of the pillars may be triangular, pyramid shaped, rectangular, hemispherical, or other suitable shape. Alternatively, the pillars may be grown or deposited in the etched region. Since there are less bonding sites for the material to bond, the overall bond strength at the weak bond region 5 is much weaker then the bonding at the strong bond regions 6.

Yet another treatment technique involves inclusion of a void area 10 (FIGS. 12 and 13), e.g., formed by etching, machining, or both (depending on the materials used) at the weak bond regions 5 in layer 1 (FIG. 12), 2 (FIG. 13). Accordingly, when the first layer 1 is bonded to the second layer 2, the void areas 10 will minimize the bonding, as compared to the strong bond regions 6, which will facilitate subsequent debonding.

Another treatment technique involves use of one or more metal regions 8 at the weak bond regions 5 of surface 1A (FIG. 2), 2A (FIG. 3), or both 1A and 2A. For example, metals including but not limited to Cu, Au, Pt, or any combination or alloy thereof may be deposited on the weak bond regions 5. Upon bonding of layers 1 and 2, the weak bond regions 5 will be weakly bonded. The strong bond regions may remain untreated (wherein the bond strength difference provides the requisite strong bond to weak bond ratio with respect to weak bond layers 5 and strong bond regions 6), or may be treated as described above or below to promote strong adhesion.

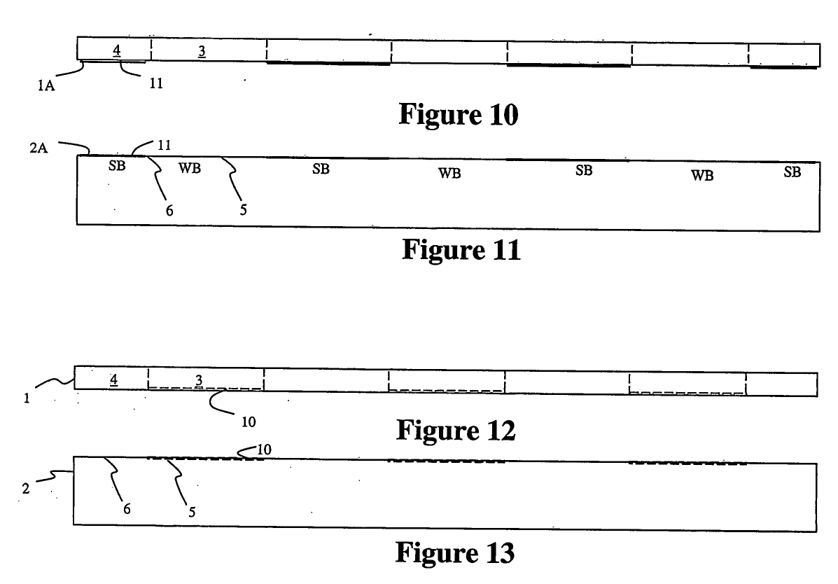

A further treatment technique involves use of one or more adhesion promoters 11 at the strong bond regions 6 on surfaces 1A (FIG. 10), 2A (FIG. 11), or both 1A and 2A. Suitable adhesion promoters include, but are not limited to, TiO₍ₓ₎, tantalum oxide, or other adhesion promoter. Alternatively, adhesion promoter may be used on substantially all of the surface 1A and/or 2A, wherein a metal material is be placed between the adhesion promoter and the surface 1A or 2A (depending on the locale of the adhesion promoter) at the weak bond regions 5. Upon bonding, therefore, the metal material will prevent strong bonding at the weak bond regions 5, whereas the adhesion promoter remaining at the strong bond regions 6 promotes strong bonding.

Yet another treatment technique involves providing varying regions of hydriphobicity and/or hydrophillicity. For example, hydrophilic regions are particularly useful for strong bond regions 6, since materials such as silicon may bond spontaneously at room temperature. Hydrophobic and hydrophilic bonding techniques are known, both at room temperature and at elevated tempertures, for example, as described in Q. Y. Tong, U. Goesle, Semiconductor Wafer Bonding, Science and Technology, pp. 49-135, John Wiley and Sons, New York, N.Y. 1999, which is incorporated by reference herein.

A still further treatment technique involves one or more exfoliation layers that are selectively irradiated. For example, one or more exfoliation layers may be placed on the surface 1A and/or 2A. Without irradiation, the exfoliation layer behaves as an adhesive. Upon exposure to irradiation, such as ultraviolet irradiation, in the weak bond regions 5, the adhesive characteristics are minimized. The useful structures may be formed in or upon the weak bond regions 5, and a subsequent ultraviolet irradiation step, or other debonding technique, may be used to separate the layers 1 and 2 at the strong bond regions 6.

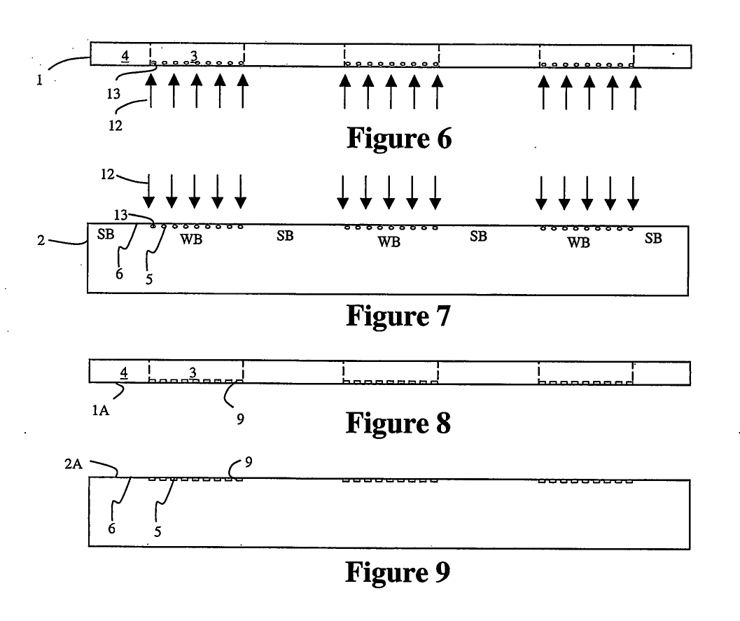

An additional treatment technique includes an implanting ions 12 (FIGS. 6 and 7) to allow formation of a plurality of microbubbles 13 in layer 1 (FIG. 6), layer 2 (FIG. 7), or both layers 1 and 2 in the weak regions 3, upon thermal treatment. Therefore, when layers 1 and 2 are bonded, the weak bond regions 5 will bond less than the strong bond regions 6, such that subsequent debonding of layers 1 and 2 at the weak bond regions 5 is facilitated.

Another treatment technique includes an ion implantation step followed by an etching step. In one embodiment, this technique is carried out with ion implantation through substantially all of the surface 1B. Subsequently, the weak bond regions 5 may be selectively etched. This method is described with reference to damage selective etching to remove defects in Simpson et al., “Implantation Induced Selective Chemical Etching of Indium Phosphide”, Electrochemical and Solid-State Letters, 4(3) G26-G27, which is incorporated by reference herein.

A further treatment technique realizes one or more layers selectively positioned at weak bond regions 5 and/or strong bond regions 6 having radiation absorbing and/or reflective characteristics, which may be based on narrow or broad band wavelength ranges. For example, one or more layers selectively positioned at strong bond regions 6 may have adhesive characteristics upon exposure to certain radiation wavelengths, such that the layer absorbs the radiation and bonds layers 1 and 2 at strong bond regions 6.

One of skill in the art will recognize that additional treatment technique may be employed, as well as combination comprising at least one of the foregoing treatment techniques. The key feature of any treatment employed, however, is the ability to form one or more region of weak bonding and one or more regions of strong bonding, providing SB/WB bond strength ratio greater than 1.

Bond Region Geometry

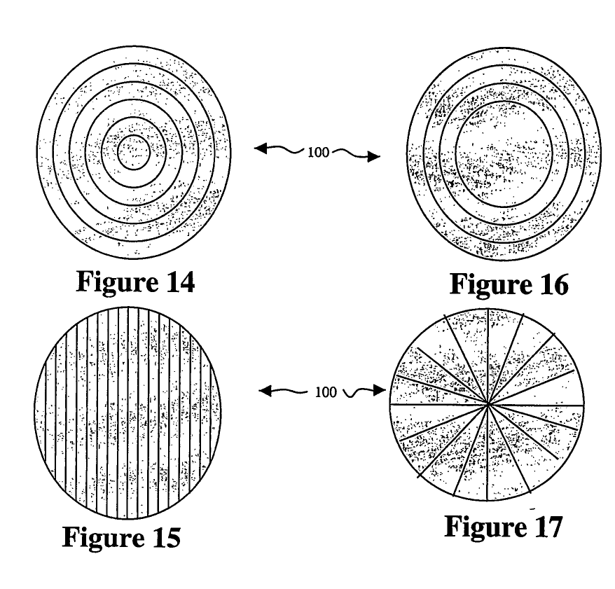

The geometry of the weak bond regions 5 and the strong bond regions 6 at the interface of layers 1 and 2 may vary depending on factors including, but not limited to, the type of photovoltaic cells or other useful structures formed on or in regions 3, the type of debonding/bonding selected, the treatment technique selected, and other factors. The regions 5, 6 may be concentric (FIGS. 14, 16 and 18), striped (FIG. 15), radiating (FIG. 17), checkered (FIG. 20), a combination of checkered and annular (FIG. 19), or any combination thereof. Of course, one of skill in the art will appreciate that any geometry may be selected. Furthermore, the ratio of the areas of weak bonding as compared to areas of strong bonding may vary. In general, the ratio provides sufficient bonding (i.e., at the strong bond regions 6) so as not to comprise the integrity of the multiple layer structure 100, especially during structure processing. Preferably, the ratio also maximizes useful regions (i.e., weak bond region 5) for structure processing.

Selective Bonding

After treatment of one or both of the surfaces 1A and 2A in substantially the locale of weak bond regions 5 and/or strong bond regions 6 as described above, layers 1 and 2 are bonded together to form a substantially integral multiple layer substrate 100. Layers 1 and 2 may be bonded together by one of a variety of techniques and/or physical phenomenon, including but not limited to, eutectic, fusion, anodic, vacuum, Van der Waals, chemical adhesion, hydrophobic phenomenon, hydrophilic phenomenon, hydrogen bonding, coulombic forces, capillary forces, very short-ranged forces, or a combination comprising at least one of the foregoing bonding techniques and/or physical phenomenon. Of course, it will be apparent to one of skill in the art that the bonding technique and/or physical phenomenon may depend in part on the one or more treatments techniques employed, the type or existence of photovoltaic devices and/or other useful structures to be formed thereon or therein, anticipated debonding method, or other factors.

Multiple layered substrate 100 thus may be used (with or without a buried oxide layer) as a starting substrate for forming photovoltaic cells, particularly in or upon regions 3, which substantially or partially overlap weak bond regions 5 at the interface of surfaces 1A and 2A. In addition to photovoltaic cells, other useful structures that may be formed in combination may include one or more active or passive elements, devices, implements, tools, channels, other useful structures, or any combination comprising at least one of the foregoing useful structures.

Debonding

After one or more photovoltaic cells or combination including other useful structures have been formed on one or more selected regions 3 of layer 1, layer 1 may be debonded by a variety of methods. It will be appreciated that since the structures are formed in or upon the regions 4, which partially or substantially overlap weak bond regions 5, debonding of layer 1 can take place while minimizing or eliminating typical detriments to the structures associated with debonding, such as structural defects or deformations.

Debonding may be accomplished by a variety of known techniques. In general, debonding may depend, at least in part, on the treatment technique, bonding technique, materials, type or existence of useful structures, or other factors.

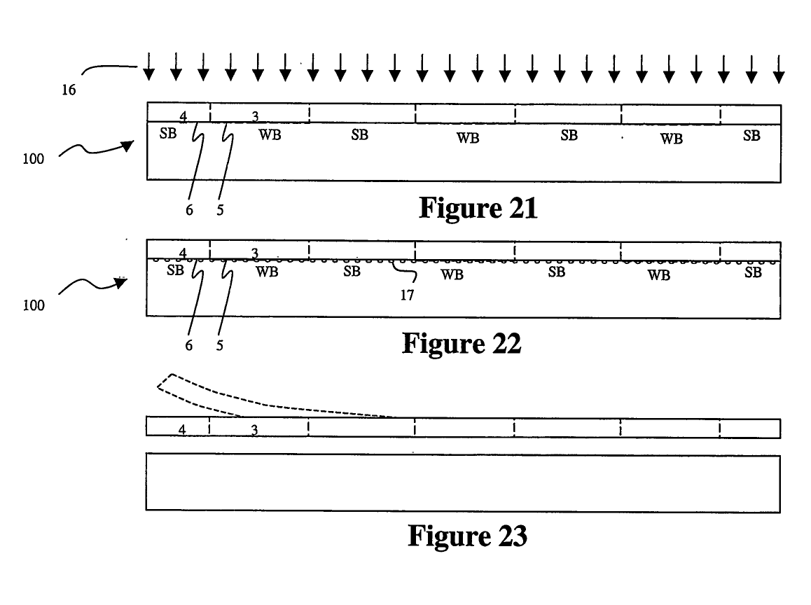

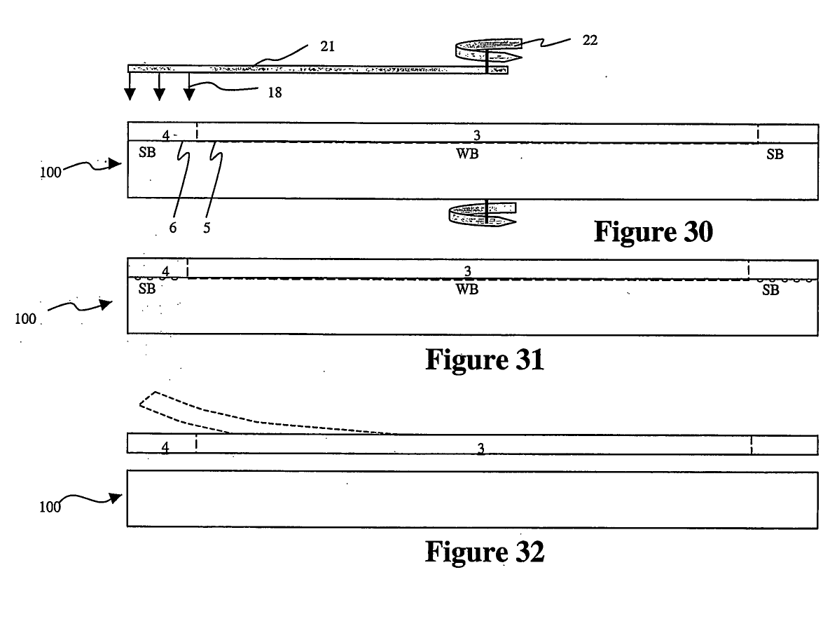

Referring in general to FIGS. 21-32, debonding techniques may based on implantation of ions or particles to form microbubbles at a reference depth, generally equivalent to thickness of the layer 1. The ions or particles may be derived from oxygen, hydrogen, helium, or other particles 14. The impanation may be followed by exposure to strong electromagnetic radiation, heat, light (e.g., infrared or ultraviolet), pressure, or a combination comprising at least one of the foregoing, to cause the particles or ions to form the microbubbles 15, and ultimately to expand and delaminate the layers 1 and 2. The implantation and optionally heat, light, and/or pressure may also be followed by a mechanical separation step (FIGS. 23, 26, 29, 32), for example, in a direction normal to the plane of the layers 1 and 2, parallel to the plane of the layers 1 and 2, at another angle with to the plane of the layers 1 and 2, in a peeling direction (indicated by broken lines in FIG. 23, 26, 29, 32), or a combination thereof. Ion implantation for separation of thin layers is described in further detail, for example, in Cheung, et al. U.S. Pat. No. 6,027,988 entitled “Method Of Separating Films From Bulk Substrates By Plasma Immersion Ion Implantation”, which is incorporated by reference herein.

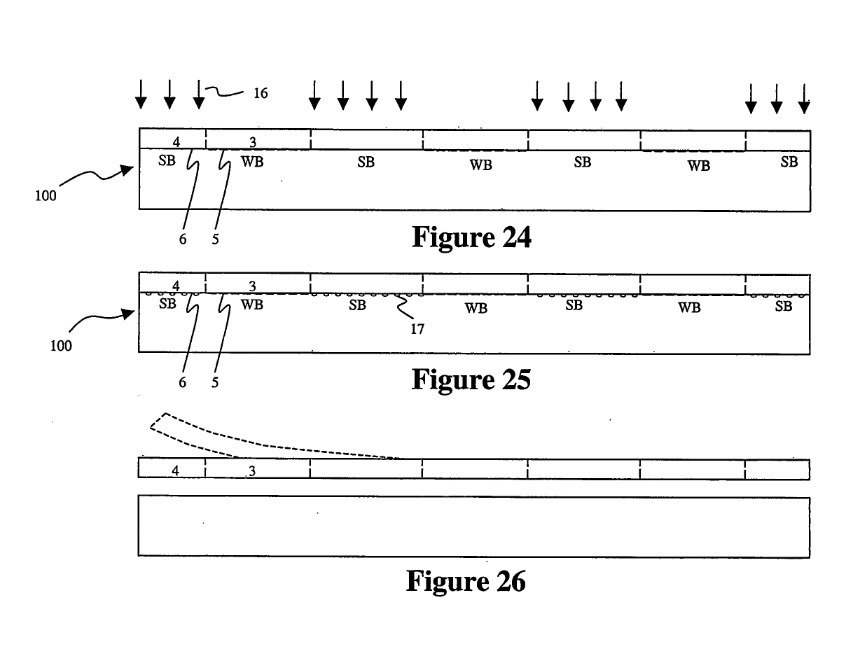

Referring particularly to FIGS. 21-23 and 24-26, the interface between layers 1 and 2 may be implanted selectively, particularly to form microbubbles 17 at the strong bond regions 6. In this manner, implantation of particles 16 at regions 3 (having one or more useful structures therein or thereon) is minimized, thus reducing the likelihood of repairable or irreparable damage that may occur to one or more useful structures in regions 3. Selective implantation may be carried out by selective ion beam scanning of the strong bond regions 4 (FIGS. 24-26) or masking of the regions 3 (FIGS. 21-23). Selective ion beam scanning refers to mechanical manipulation of the structure 100 and/or a device used to direct ions or particles to be implanted. As is known to those skilled in the art, various apparatus and techniques may be employed to carry out selective scanning, including but not limited to focused ion beam and electromagnetic beams. Further, various masking materials and technique are also well known in the art.

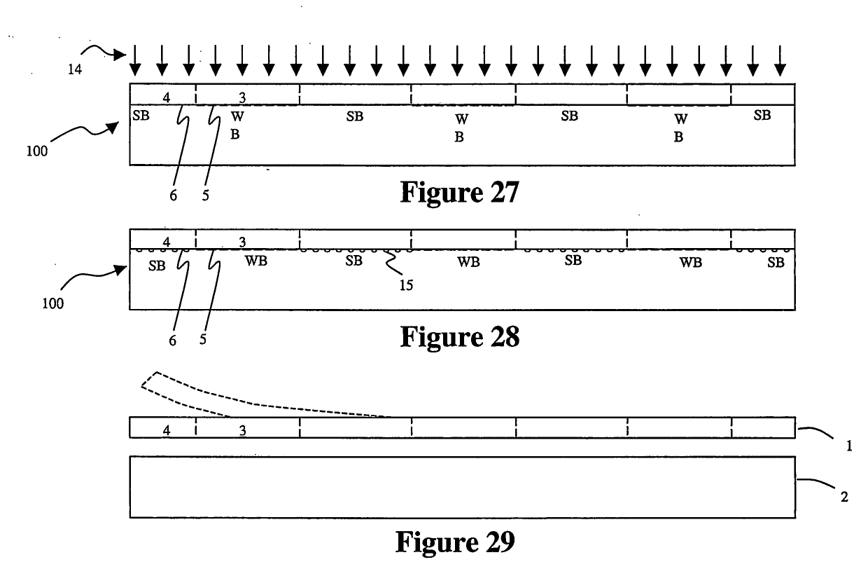

Referring to FIGS. 27-29, the implantation may be effectuated substantially across the entire the surface 1B or 2B. Implantation is at suitable levels depending on the target and implanted materials and desired depth of implantation. Thus, where layer 2 is much thicker than layer 1, it may not be practical to implant through surface 2B; however, if layer 2 is a suitable implantation thickness (e.g., within feasible implantation energies), it may be desirable to implant through the surface 2B. This minimizes or eliminates possibility of repairable or irreparable damage that may occur to one or more useful structures in regions 3.

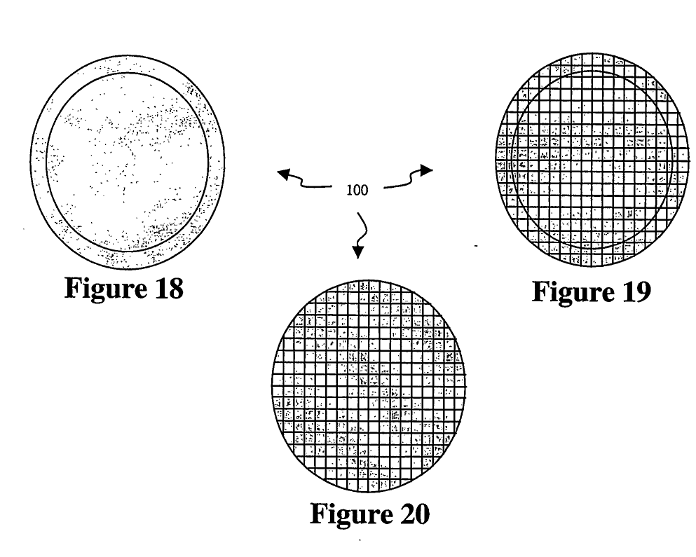

In one embodiment, and referring to FIGS. 18 and 30-32, strong bond regions 6 are formed at the outer periphery of the interface between layers 1 and 2. Accordingly, to debond layer 1 form layer 2, ions 18 may be implanted, for example, through region 4 to form microbubbles at the interface of layers 1 and 2. Preferably, selective scanning is used, wherein the structure 100 may be rotated (indicated by arrow 20), a scanning device 21 may be rotated (indicated by arrow 22), or a combination thereof. In this embodiment, a further advantage is the flexibility afforded the end user in selecting useful structures for formation therein or thereon. The dimensions of the strong bond region 6 (i.e., the width) are suitable to maintain mechanical and thermal integrity of the multiple layer substrate 100. Preferably, the dimension of the strong bond region 6 is minimized, thus maximizing the area of weak bond region 5 for structure processing. For example, strong bond region 6 may be about one (1) micron of an eight (8) inch water.

Further, debonding of layer 1 from layer 2 may be initiated by other conventional methods, such as etching (parallel to surface), for example, to form an etch through strong bond regions 6. In such embodiments, the treatment technique is particularly compatible, for example wherein the strong bond region 6 is treated with an oxide layer that has a much higher etch selectivity that the bulk material (i.e., layers 1 and 2). The weak bond regions 5 preferably do not require etching to debond layer 1 from layer 2 at the locale of weak bond regions 5, since the selected treatment, or lack thereof, prevented bonding in the step of bonding layer 1 to layer 2.

Alternatively, cleavage propagation may be used to initiate debonding of layer 1 from layer 2. Again, the debonding preferably is only required at the locale of the strong bond regions 6, since the bond at the weak bond regions 5 is limited. Further, debonding may be initiated by etching (normal to surface), as is conventionally known, preferably limited to the locales of regions 4 (i.e., partially or substantially overlapping the strong bond regions 6).

In another embodiment, and referring now to FIG. 85, a method of debonding is shown. The method includes providing a multiple layered substrate; processing one or more useful structures (not shown) in the WB regions; etching away at the SB regions, preferably at a tapered angle (e.g., 45 degrees); subjecting the device layer, preferably only the etched SB region, to low energy ion implantation; and peeling or otherwise readily removing the device layer portions at the WB region. Note that while two device layer portions at the WB layer are shown as being removed, it is understood that this may be used to facilitate release on one device layer portion. The tapered edge of the WB region mechanically facilitates removal. Beneficially, much lower ion implant energy may be used as compared to implant energy required to penetrate the original device layer thickness.

Materials

Layers 1 and 2 may be the same or different materials, and may include materials including, but not limited to, plastic (e.g., polycarbonate), metal, semiconductor, insulator, monocrystalline, amorphous, noncrystalline, organic materials, or a combination comprising at least one of the foregoing types of materials. For example, specific types of materials include silicon (e.g., monocrystalline, polycrystalline, noncrystalline, polysilicon, and derivatives such as Si₃N₄, SiC, SiO₂), GaAs, InP, CdSe, CdTe, SiGe, GaAsP, GaN, SiC, GaAlAs, InAs, AlGaSb, InGaAs, ZnS, AlN, TiN, other group IIIA-VA materials, group IIB materials, group VIA materials, sapphire, quartz (crystal or glass), diamond, silica and/or silicate based material, liquid crystalline material, polymeric materials (insulative, conducting or semi-conducting) or any combination comprising at least one of the foregoing materials. Of course, processing of other types of materials may benefit from the process described herein to provide multiple layer substrates 100 of desired composition.

Benefits of Multiple Layer Substrate

An important benefit of the instant method and resulting multiple layer substrate, or thin film derived from the multiple layer substrate is that the structures are formed in or upon the regions 3, which partially or substantially overlap the weak bond regions 5. This substantially minimizes or eliminates likelihood of damage to the photovoltaic cells or other structures when the layer 1 is removed from layer 2. The debonding step generally requires intrusion (e.g., with ion implantation), force application, or other techniques required to debond layers 1 and 2. Since, in certain embodiments, the structures are in or upon regions 3 that do not need local intrusion, force application, or other process steps that may damage, reparably or irreparable, the structures, the layer 1 may be removed, and structures derived therefrom, without subsequent processing to repair the structures. The regions 4 partially or substantially overlapping the strong bond regions 6 do generally not have structures thereon, therefore these regions 4 may be subjected to intrusion or force without damage to the structures.

The layer 1 may be removed as a self supported film or a supported film. For example, handles are commonly employed for attachment to layer 1 such that layer 1 may be removed from layer 2, and remain supported by the handle. Generally, the handle may be used to subsequently place the film or a portion thereof (e.g., having one or more useful structures) on an intended substrate, another processed film, or alternatively remain on the handle. Such handlers are known in the art. One such handler is described in PCT Application Serial No. PCT/US02/31348, filed Oct. 2, 2002, entitled “Device And Method For Handling Fragile Objects, And Manufacturing Method Thereof”, which is incorporated herein by reference in its entirety.

One benefit of the instant method is that the material constituting layer 2 is may be reused and recycled. A single wafer may be used, for example, to derive layer 1 by any known method. The derived layer 1 may be selectively bonded to the remaining portion (layer 2) as described above. When the thin film is debonded, the process is repeated, using the remaining portion of layer 2 to obtain a thin film to be used as the next layer 1. This may be repeated until it no longer becomes feasible or practical to use the remaining portion of layer 2 to derive a thin film for layer 1.

Photovoltaic Cells Processing in or on the Multiple Layered Substrate

Solar or photovoltaic cells may be formed in or upon regions 3, which partially or substantially overlap weak bond regions 5. Accordingly, regions 4, which partially or substantially overlap strong bond regions 6, generally do not have cells therein or thereon. Therefore, as described, the multiple layer substrate 100 is formed such that any type of solar or photovoltaic cell may be processed using conventional fabrication techniques, or other techniques that become known as the various related technologies develop. Certain fabrication techniques subject the substrate to extreme conditions, such as high temperatures, pressures, harsh chemicals, or a combination thereof. Thus, the multiple layer substrate 100 is preferably formed so as to withstand these conditions.

After processing of solar or photovoltaic cells within or upon layer 1 of the multiple layer substrate 100, layer 1 may subsequently be debonded. The debonding may be by any known technique, such as peeling, without the need to directly subject the solar cells to detrimental delamination techniques. Since solar cells are not generally formed in or on regions 4, these regions may be subjected to debonding processing, such as ion implantation, without detriment to the cells formed in or on regions 3.

Using the above described multiple layered substrate for processing, the debonded layer having the solar or photovoltaic cells may comprise a very thin layer. Since the layer having the cells are supported on a substrate that is readily debonded, it may be as thin as 5 micrometers, or even 2 micrometers, as compared to present cells having thicknesses of 500 micrometers.

Photovoltaic cells include any device used for direct solar-electric conversion. Heretofore, the limitation of photovoltaic cells related to the excessive cost of manufacture, preventing use thereof for the world's large-scale electricity demands. It is contemplated that any type of known photovoltaic cell, or those developed as the art of photovoltaic cells evolves, may be processed according to the present invention. Types of photovoltaic cells include, but are not limited to, pn junction; back surface field; violet; textured; V-groove multijunction; organic; photosynthesis based energy conversion.

Typical pn junction photovoltaic cells include a shallow pn junction formed on the surface (e.g., by diffusion) created by doping of the substrate (i.e., the layer to be debonded) with atoms from an element with one more or less electrons than occurs in the substrate. Metallic or other conducting materials are used to form a front ohmic contact stripe and fingers and a back ohmic contact that covers the entire back surface. Thus, in the weak bond areas, pn junctures may be formed and metallized. The weak bond areas (at layer 1, layer 2, or both), may be metallized prior to doping. After processing, the layer may be debonded as described above, removing the solar or photovoltaic cells with little or no damage thereto.

In alternative embodiments, optional layers may be incorporated in the cells, generally to absorb or reflect UV wavelengths. Additionally, a cholesteric liquid crystal layer may be included to absorb or reflect IR wavelengths.

In addition to the pn junction cells described above, other types of solar cells may be processed on the multiple layered substrate 100. One type of solar cell that may be formed in or upon the weak bonding regions is a “back surface field” (BSF) cell. In this type of cell, the front surface is formed as described above. The back of the cell, instead of containing a metallic ohmic contact, includes a very heavily doped region adjacent to the contact. This doped region may be formed prior to bonding of the layers 1 and 2 at the weak bond areas.

Still a further type of cell that may be processed in or upon the weak bonding regions is known as a “violet” cell, which is fabricated with reduced surface doping concentration and smaller junction depth. This type of cell offers improved response at high photon energies.

Yet another type of cell that may be processed in or upon the weak bonding regions is known as a “textured” cell, having pyramidal surfaces. These pyramidal surfaces may be produced by anisotropical etching of (100) oriented Si surface. When in use, light incident on the side of a pyramid will be reflected onto another pyramid instead of being lost, greatly increasing operating efficiencies.

Another type of cell that may be processed in or upon the weak bonding regions is known as a V-groove multijunction solar cell, wherein many individual pnn (or ppn) trapezoidal shaped diode elements are connected in series. The shape of the diode elements may be defined by anisotropically etching (100) Si through a thermally grown silicon dioxide layer.

Of course, one of skill in the art will appreciate that these and other known and future developed types of solar cells may be processed in or upon the weak bonding regions of the multiple layered substrate 100.

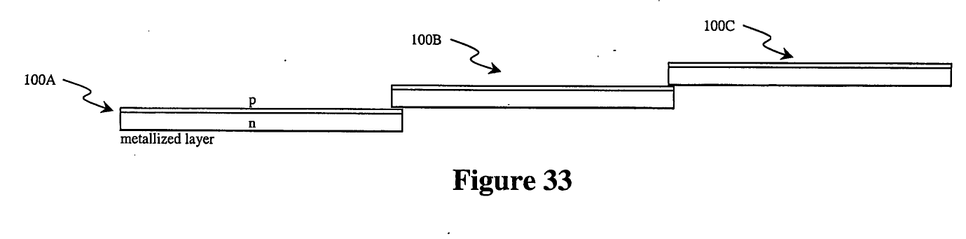

Referring now to FIG. 33, a solar cell set 100 includes cells 110A, 110B and 110C. Each cell includes a metallized layer and a pn juncture, formed as described above. The cells 110A, 110B and 110C are stacked and bonded on the layers at the top surfaces 112A, 112B, 112C (i.e., solar capture surfaces) on one distal side of the cells (i.e., the same side for each). This configuration allows for a large solar capture surface area, particularly as compared to the thickness of the solar cell set 100. The cells may be supported on a cheap, flexible substrate, for example, glass, polycarbonate, glass, plastic, polyurethane, wood, paper, metal (e.g., with insulator).

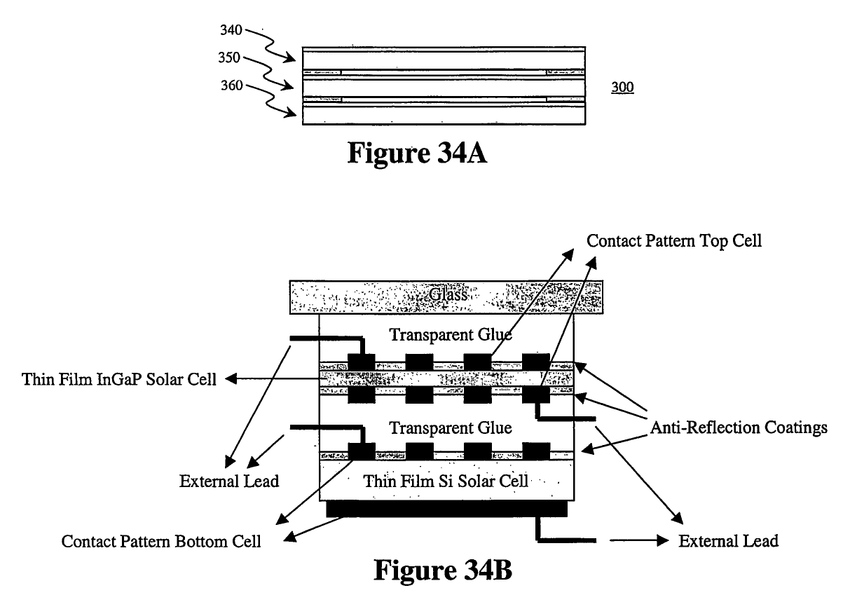

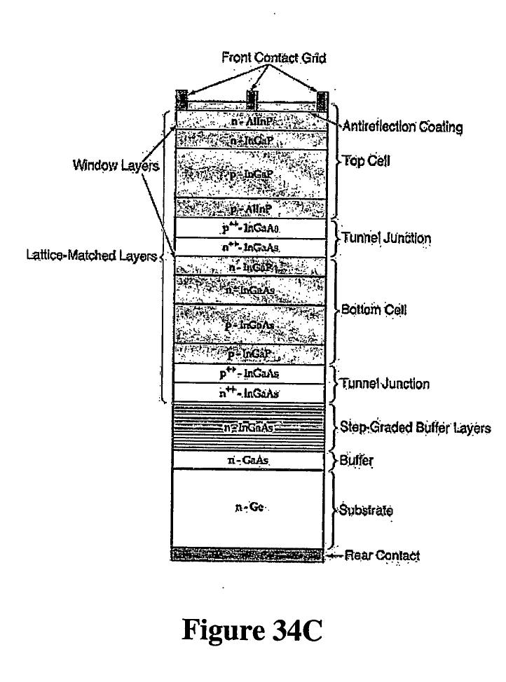

Referring to FIG. 34A, a tandem solar cell 300 may be formed, generally using plural solar cells sets 340, 350 and 360, each suitable for a different range of spectral conversion. The top cell set 340 absorbs the UV radiation and photons corresponding to the E_{g} of that cell. The middle cell set 350 absorbs a lower bandgap E_{g} than that of the set 340. The lowermost cell set 360 absorbs a lower bandgap E_{g} than that of the set 350. In this manner, a larger portion of the bandgap may be converted to energy. varying cells (i.e., having different E_{g} values) may be stacked to maximize efficiency, greater than about 30%.

Each of the cells sets are interconnected to transfer the electrical energy created to a common set of output terminals. The interconnect between layers may be between the layers, on the sides of the layers, or both. Using the techniques described in the '909 application, as well as a handle described in PCT Application Serial No. PCT/US02/31348, filed Oct. 2, 2002, entitled “Device And Method For Handling Fragile Objects, And Manufacturing Method Thereof”, which is incorporated herein by reference in its entirety, interconnects between layers may be formed based generally on conventional systems in a cost efficient and reliable manner.

For example, in a mechanically stacked tandem solar cell, various solar cells are layered to form a spectrally broad photovoltaic cell. Referring now to FIG. 34B, a basic scheme of a Si/InGap thin film mechanically stacked tandem solar cell is shown. A thin film InGaP solar cell will be mounted on a silicon bottom cell. Optimally, the absorption of the blue part of the solar spectrum by the top cell is maximized. Further, the design of contact patterns and anti-reflection coatings are preferably optimized to minimize light blockage at the cell surface. Additionally, mechanically stacked tandem solar cell should be constructed with a minimum efficiency loss due to handling damage of the thin film or bad optical coupling. Using the techniques described in herein for processing photovoltaic devices in weak bond regions of a multiple layered substrate, and using suitable handler devices, the problems of handling damage and bad optical coupling may be minimized or eliminated.

Referring now to FIG. 34C, a monolithical tandem solar cell is depicted. Specifically, a monolithical InₓGa₁₋ₓAs/InₓGa₁₋ₓP-on-Ge tandem cell structure is shown for exemplary purposes. For monolithical tandem solar cells, the interconnection between the individual elements of the cascade is typically done by use of a tunnel junction (as shown in FIG. 34C), which requires high doping levels to operate. This junction will aid the flow of electrons between the cells, and the front and rear contact will provide collection of current.

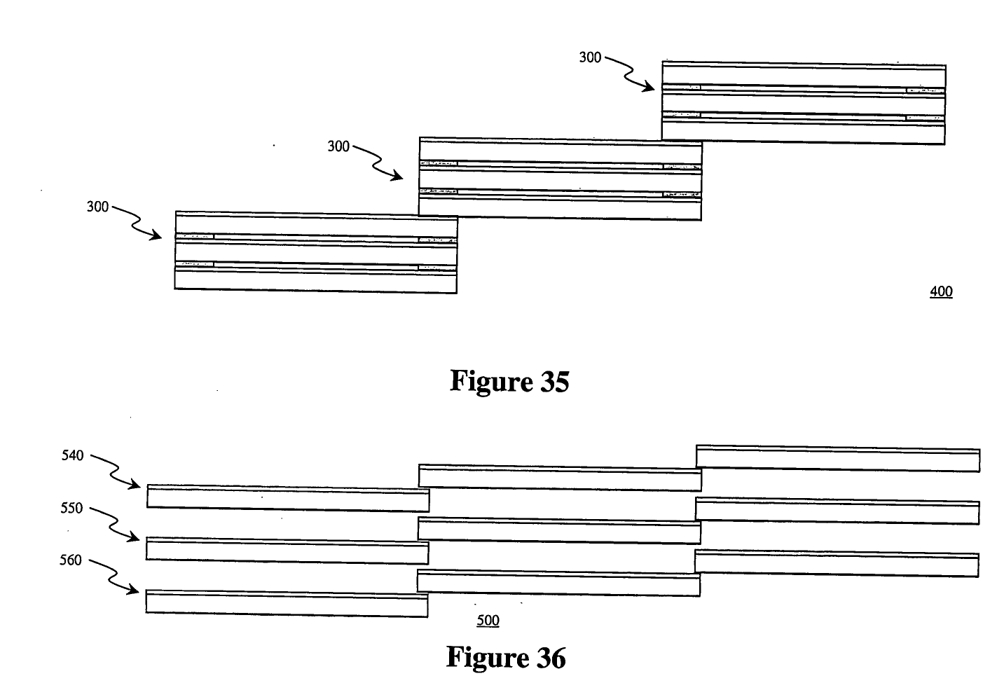

Referring to FIG. 35, a tandem solar cell set may be formed using several tandem solar cells 300. The tandem solar cells 300 may be aligned and bonded on the edges of the top surface, for example, as described with respect to FIG. 33 (as related to single spectral conversion cells). Using this configuration, the overall structure may, therefore, be very thin, for example, less than 15 um. Also, because of the direct contact interconnect scheme between cells, this configuration will reduce the area blocked by interconnect wiring and thus increase the active area for sunlight absorption. The entire tandem solar cell set 400 may be supported on an inexpensive substrate, as needed. For example, a flexible substrate may be used, since the solar cell layers are very thin and inherently flexible.

In another embodiment, and referring now to FIG. 36, different solar cell sets 540, 550 and 560, each intended for generally different bandwidth gaps, may be formed (i.e., as described with respect to FIG. 33). These layers may then be stacked and interconnected, forming a tandem solar cell set 500.

The materials used to form the solar cells may generally be any of those known in the art and described above related to the layers of the multiple layered substrate. In general, semiconductors with bandgaps between 1 and 2 eV may be considered solar cell materials. Such materials include, but are not limited to, silicon (single-crystal, polycrystalline, amorphous thin-film), III-V semiconductors, CdS, GaAs, InP, CdTe, CuInSe₂, the like, and combinations comprising at least one of the foregoing. Further, organic materials may be used in organic photovoltaic cells to create an excitation structure necessary to convert photon energy into electrical charge, such as fullerenes, conductive polymers, pentacene, liquid crystal hexa-perihexabenzocoronene (HPBC), perylene dye, these materials being used alone or in combination with each other or other suitable materials.

In thin film solar cells, the support layer may include electrically active or passive substrates, such as glass, plastic, ceramic, metal, graphite, or metallurgical silicon. Thus, as described herein, a solar cell or solar cell set may be formed in weak bond regions of a manufacturing support substrate, and subsequently debonded and adhered to or otherwise placed in an end use support layer.

It will be apparent to one skilled in the art that a balance must be had between the cost of the materials and the desired efficiencies. However, with the techniques described herein, since very thin layers of solar cells may be used, the material costs can be substantially reduced, allowing favor in the balance toward higher cost solar materials having great spectral conversion efficiencies.

Substantial benefits may be derived from the present invention. Over 40% efficiency may be possible at very low cost, since the manufacturing method allows for use of very thin layers of material, and reuse of the substrate is possible after debonding.

While preferred embodiments have been shown and described, various modifications and substitutions may be made thereto without departing from the spirit and scope of the invention. Accordingly, it is to be understood that the present invention has been described by way of illustrations and not limitation.

1. A photovoltaic cell structure comprising:
a p-n junction formed on one or more regions of a solar cell material layer, wherein the solar cell material layer is removed from a support layer.

2. The photovoltaic cell as in claim 1, wherein the solar cell material layer and the support layer are essentially the same material.

3. The photovoltaic cell as in claim 1, wherein the solar cell material layer is bonded to the support layer prior to formation of the p-n junction.

4. The photovoltaic cell as in claim 1, wherein the solar cell material layer is selectively bonded to the support layer prior to formation of the p-n junction.

5. A photovoltaic cell set comprising a first photovoltaic cell as in claim 1 and a second photovoltaic cell as in claim 1, each photovoltaic cell including a solar capture surface, a back surface, a first distal side and a second distal side, wherein the first distal side of the solar capture surface of the first photovoltaic cell is bonded to the second distal side of the back surface of the second photovoltaic cell.

6. The photovoltaic cell set as in claim 5, further comprising a third photovoltaic cell, wherein the first distal side of the solar capture surface of the second photovoltaic cell is bonded to the second distal side of the back surface of the third photovoltaic cell.

7. A method of manufacturing a photovoltaic cell comprising:
bonding a photovoltaic cell layer to a substrate layer at selective locales to define one or more regions of weak bonding and one or more regions of strong bonding;
processing one or more photovoltaic cells in the one or more regions of weak bonding.

8. The method as in claim 7, further comprising removing the one or more photovoltaic cells by debonding the one or more regions of strong bonding.

9. The method as in claim 8, further comprising removing a layer of the substrate layer and bonding the removed layer of substrate to the remaining substrate layer at selective locales to define one or more regions of weak bonding and one or more regions of strong bonding, thereby recycling the substrate layer.

10. A method of manufacturing a photovoltaic cell comprising:
providing a multiple layered substrate having a device layer and a substrate layer, the device layer selectively bonded to the substrate layer to define one or more regions of weak bonding and one or more regions of strong bonding;
processing one or more photovoltaic cells in the device layer at one or more regions of weak bonding;
removing the device layer from the substrate layer by debonding the strong bond regions, thereafter allowing removal of the device layer with minimal or no damage to the processed photovoltaic cells in the device layer.

11. The method of claim 7, wherein the photovoltaic cell comprises a cell selected from the group consisting of p-n junction, back surface field, violet; textured, V-groove multijunction, organic, photosynthesis based energy conversion, and combinations comprising at least one of the foregoing.

12. A method of manufacturing a photovoltaic cell comprising:
providing a first multiple layered substrate having a first device layer and a first substrate layer, the first device layer selectively bonded to the first substrate layer to define one or more regions of weak bonding and one or more regions of strong bonding;
processing a first photovoltaic cell in the first device layer at one or more regions of weak bonding;
removing the first device layer from the first substrate layer by debonding the strong bond regions, thereafter allowing removal of the first device layer with minimal or no damage to the processed photovoltaic cells in the first device layer;
providing a second multiple layered substrate having a second device layer and a second substrate layer, the second device layer selectively bonded to the second substrate layer to define one or more regions of weak bonding and one or more regions of strong bonding;
processing a second photovoltaic cell in the second device layer at one or more regions of weak bonding;
removing the second device layer from the second substrate layer by debonding the strong bond regions, thereafter allowing removal of the second device layer with minimal or no damage to the processed photovoltaic cells in the second device layer; and
stacking and bonding the first device layer to the second device layer at a distal edge of the layers to form a photovoltaic cell set.

13. A method of manufacturing a tandem photovoltaic cell comprising:
providing a first photovoltaic cell formed according to the method of claim 7, having a bandgap E_{g}(1); and
stacking a second photovoltaic cell formed according to the method of claim 7, having a bandgap E_{g}(2), atop the first photovoltaic cell, wherein E_{g}(1) is power than E_{g}(2), thereby provising a tandem photovoltaic cell.

14. The photovoltaic cell as in claim 4, wherein the selective bonding comprises regions of weak bonding and regions of strong bonding, wherein the p-n junctions are formed in the regions of weak bonding on the solar cell material layer, whereby the solar cell material layer is debonded from the support layer by processing the strong bond regions and minimally invading the weak bond regions, further whereby the photovoltaic cell formed in the weak bond region required little or no repair subsequent debonding.

15. The method of claim 10, wherein the photovoltaic cell comprises a cell selected from the group consisting of p-n junction, back surface field, violet; textured, V-groove multijunction, organic, photosynthesis based energy conversion, and combinations comprising at least one of the foregoing.

16. A method of manufacturing a tandem photovoltaic cell comprising:
providing a first photovoltaic cell formed according to the method of claim 10, having a bandgap E_{g}(1); and
stacking a second photovoltaic cell formed according to the method of claim 10, having a bandgap E_{g}(2), atop the first photovoltaic cell, wherein E_{g}(1) is power than E_{g}(2), thereby provising a tandem photovoltaic cell.

17. A method of manufacturing a tandem photovoltaic cell comprising:
providing a first photovoltaic cell formed according to the method of claim 12, having a bandgap E_{g}(1); and
stacking a second photovoltaic cell formed according to the method of claim 12, having a bandgap E_{g}(2), atop the first photovoltaic cell, wherein E_{g}(1) is power than E_{g}(2), thereby provising a tandem photovoltaic cell.
